(19) United States
(12) Patent Application Publication
(10) Pub. No.: US 2009/0091322 A1
(43) Pub. Date: Apr. 9, 2009

(54) Single-shot magnetic resonance spectroscopic imaging with partial parallel imaging

(76) Inventor: Stefan Posse, Albuquerque, NM (US)

Correspondence Address: Stefan Posse, 1616 Bayita Ln NW, Albuquerque, NM, 87107, US

(21) Appl. No.: 12/148,993

(22) Filed: Apr. 24, 2008

Related U.S. Application Data
(60) Provisional application No. 60/926,160, filed on Apr. 25, 2007.

(51) Int. Cl. G01R 33/54

(52) U.S. Cl. 324/307

(57) ABSTRACT

The present invention has a magnetic resonance spectroscopic imaging (MRSI) method that allows collecting a complete spectroscopic image with one spectral dimension and up to three spatial dimensions in a single signal excitation. The method employs echo-planar spatial-spectral encoding combined with phase encoding interleaved into the echo-planar readout train and partial parallel imaging to reconstruct spatially localized absorption mode spectra. This approach enables flexible tradeoff between gradient and RF encoding to maximize spectral width and spatial resolution. Partial parallel imaging (e.g. SENSE or GRAPPA) is employed with this methodology to accelerate the phase encoding dimension. A preferred implementation is with the recently developed superresolution parallel MRI method, which accelerates along both the readout and phase encoding dimensions and thus enables particularly large spectral width and spatial resolution. The symmetrical k-space trajectory of this methodology is designed to compensate phase errors due to convolution of spatial and spectral encoding. This method is suitable for hyperpolarized MRSI, spatial mapping of the diffusion coefficients of biochemicals and functional MRI using quantitative mapping of water relaxation.

### REFERENCE TO RELATED APPLICATIONS

Applicant claims priority of U.S. Provisional Application No. 60/926,160, filed on Apr. 25, 2007 for SINGLE-SHOT MAGNETIC RESONANCE SPECTROSCOPIC IMAGING WITH PARTIAL PARALLEL IMAGING of Stefan Posse, Applicant herein.

### FEDERALLY SPONSORED RESEARCH

The present invention was made with government support under Grant No. 1 R01 DA14178-01 awarded by the National Institutes of Health. As a result, the Government has certain rights in this invention.

### BACKGROUND OF THE INVENTION

1. Technical Field of the Invention

This invention relates to a magnetic resonance spectroscopic imaging (MRSI) method, specifically to a magnetic resonance spectroscopic imaging method that acquires up to three spatial dimensions and one spectral dimension in a single signal excitation. The method employs echo-planar spatial-spectral encoding combined with interleaved phase encoding and partial parallel imaging. Preferred uses are hyperpolarized MRSI, diffusion sensitive MRSI, MRSI in moving organs in humans and animals, quantitative functional MRI (fMRI), and spatial mapping of chemical reactions.

2. Description of the Prior Art

High-Speed MRSI

Conventional MRSI techniques require one phase encoding step for each encoded image element. One method of reducing the data acquisition time of MRSI is to acquire multiple individually phase-encoded spin echoes in a single RF excitation (1). Much faster spatial-spectral encoding can be achieved using either echo planar imaging (EPI) (2) or spiral readouts (3). A number of laboratories have developed high-speed MRSI methods (4,5,6,7), mostly using echo-planar and spiral readout modules, that provide considerable acceleration as compared to conventional phase encoded MRSI. We have developed Proton-Echo-Planar-Spectroscopic-Imaging (PEPSI) uses echo-planar readouts to accelerate spatial encoding times by more than one order of magnitude to measure 2-dimensional metabolite distributions at short TE and 3-dimensional metabolite distributions (8,9,10). PEPSI has also been employed for time-resolved metabolic imaging to dynamically map lactate concentrations during respiratory and metabolic challenges (11,12), to characterize metabolic dysfunction during sodium-lactate infusion in patients with panic disorder (13) and to map multiplet resonance in human brain at short echo time and high field strength (14).

Ultra High-Speed MRSI Methods

Recently, Mayer et al. described fast metabolic imaging of systems with sparse spectra for applications in hyperpolarized ¹³C imaging (15). The imaging method in that study was based on spiral readout encoding and enabled single-shot mapping of ¹³C spectra in seconds, albeit at narrow spectral width, which required separate reconstruction of each spectral peak. In a follow-up publication, Levin et al. described a least squares reconstruction to optimize fast spiral spectroscopic imaging by taking into account chemical shift evolution during the readout period (16). Both methods are most suitable for sparse spectra with well separated peaks, since spectral width is narrow. Reconstruction of absorption mode spectra with these methods is only feasible over a narrow spectral width and only for spectra with a few distinct spectral peaks.

Acceleration of MRSI Using Parallel Imaging

Recent advances in parallel MRI employing information from different channels in an RF coil array enable considerable acceleration of MRSI. Dydak et al. demonstrated acceleration of conventional phase encoded MRSI with acquisition times of just a few minutes (17,18) using SENSE (19). Recently, we have developed even faster spatial-spectral encoding by combining Proton-Echo-Planar-Spectroscopic-Imaging (PEPSI) with parallel imaging to obtain minimum encoding times of 1 min for 3D encoding of a 32×32×8 matrix (20) and 2D encoding times as short as 16 s for a 32×32 matrix (21,22) using SENSE and GRAPPA (23). However, single-shot MRSI encoding is not feasible with these methods.

Acceleration Using Superresolution MRI

Another recent innovation developed by Otazo et al. (24,25) is intra-voxel encoding parallel MRI (pMRI) technique, which is a form of SUperREsolution (SURE) imaging based on SENSE reconstruction (SURE-SENSE). It accelerates image encoding by acquiring a fully sampled low spatial resolution representation of the object being imaged and reconstructs the image with higher target spatial resolution using intra-voxel coil sensitivity variations measured in coil sensitivity maps at target resolution. This approach has the following two major advantages as compared to current pMRI techniques: (a) Acceleration along both the readout and the phase encoding direction(s) of any MRI technique thus enabling a large overall acceleration factor. (b) Encoding matrix suitable for efficient regularization providing a small and spatially-uniform g-factor. The trade-off of SURE-SENSE is a slight loss in spatial resolution as compared to conventional pMRI techniques. The increase in spatial resolution with this method is determined by the degree of coil sensitivity variation within the low resolution image voxel. The method is applicable to receiver arrays with a large number of small elements which provide strong spatial variation of the coil sensitivity maps. A pre-conditioned conjugate gradient algorithm is used to solve the intrinsically ill-conditioned system with minimal noise amplification. Superresolution Sensitivity-Encoding (SURE-SENSE) represents an alternative to standard SENSE for the same acquisition time and it is advantageous for low spatial resolution where the residual aliasing from intra-voxel coil sensitivity variation is removed. The method is particularly suitable to enhance the spatial resolution and reduce ringing artifacts in intrinsically low spatial resolution imaging modalities such as spectroscopic and functional imaging. We have show feasibility of in vivo human brain structural and spectroscopic imaging using receiver arrays with 32 and 96 elements. SURE-SENSE provides flexibility in trading off spatial and temporal resolution for clinical studies of spectroscopic and functional imaging. However, single shot MRSI encoding is not feasible with this methodology.

High-Speed MR Spectroscopic Imaging has Important Applications.

The development of hyperpolarized MRI agents presents both unprecedented opportunities and new technical challenges. In particular, with signal-to-noise ratio (SNR) enhancements on the order of the 10000-fold, dynamic nuclear polarization of metabolically active substrates (e.g., 13C-labeled pyruvate or acetate) theoretically permits in vivo imaging of not only the injected agent, but also downstream metabolic products. This feature of hyperpolarized MR spectroscopy (MRS) provides investigators a unique opportunity to non-invasively monitor critical dynamic metabolic processes in vivo under both normal and pathologic conditions. The development of hyperpolarized MRI agents presented unprecedented sensitivity for imaging metabolically active substrates (e.g., ¹³C-labeled pyruvate or acetate) and downstream metabolic products for tumor diagnosis and treatment monitoring (26,27,28), as well as assessment of cardiac function (29). In studies using hyperpolarized samples, the magnetization decays toward its thermal equilibrium value in 10s of seconds and is not recoverable. Ultra-high-speed MRSI methods, preferably with single-shot encoding, are necessary to capture the metabolic dynamics in hyperpolarized MRSI and to minimize blurring of the point spread function due to the signal decay.

A recent study by Golman et al. (26) described real-time metabolic imaging. NMR spectroscopy has until now been the only noninvasive method to gain insight into the fate of pyruvate in the body, but the low NMR sensitivity even at high field strength has only allowed information about steady-state conditions. The medically relevant information about the distribution, localization, and metabolic rate of the substance during the first minute after the injection has not been obtainable. Use of a hyperpolarization technique has enabled 10-15% polarization of 13C in up to a 0.3 Mpyruvate solution. i.v. injection of the solution into rats and pigs allows imaging of the distribution of pyruvate and mapping of its major metabolites lactate and alanine within a time frame of 10 s. Hyperpolarized MRS is currently being developed by major manufacturers and expected to be of considerable commercial value.

Another possible application of high-speed MRSI is spatial mapping of metabolite diffusion coefficients. The apparent diffusion coefficient (ADC) of metabolites reflects several biophysical parameters such as viscosity, cell swelling, restriction in subcellular structures, cytoplasmic streaming, etc. that are complementary to intra- and extra-cellular water mobility measured with diffusion sensitive MRI (30,31,32). Spatial mapping of metabolite diffusion in vivo with current phase encoded MRSI techniques is challenging due to strong motion sensitivity that results in serious degradation of spatial localization, even when using motion correction based on navigator signals (33,34). Single-shot MRSI would have a similar impact on the feasibility of metabolite diffusion mapping as EPI had on diffusion MRI (35).

High-speed MRSI is also applicable to biochemical imaging in moving organs, such as heart or breast, since MRSI is sensitive to movement artifact that results in blurring of the image. For example, mapping of metabolic tumor markers in the breast using proton MRSI is challenging due to chest movement and the large dynamic range of measured signals, ranging from Choline to strong lipid signals from adipose tissue (36,37). Gating to the heart beat is frequently used to reduce motion artifact, but this reduces data acquisition efficiency. Simultaneous synchronization to respiration may be required to further reduce motion artifacts, which additionally reduces data acquisition efficiency. Gating in the presence of irregular heart beat introduces variability in repetition time that results in non steady-state signal intensity and distortion of the image encoding process. Image registration during post-processing is challenging due to the highly nonlinear movement pattern within the chest. Single-shot encoding would significantly reduce motion related localization artifact and contamination from extraneous lipids.

MR spectroscopic imaging in organs, like the brain, is sensitive to localized signal fluctuations due to blood pulsation or other physiological movement mechanisms (e.g. CSF movement) that results in blurring of the image. Gating to the rhythm of the physiological fluctuation (e.g. heart beat) can be used to reduce this artifact, but this reduces data acquisition efficiency. Gating in the presence of irregular heart beat introduces variability in repetition time that results in non steady-state signal intensity and distortion of the image encoding process. Therefore, fast spectroscopic imaging acquisition schemes are important.

Functional MRI is widely used to map changes in brain activation in animals and humans. However, the methodology lacks quantification due complex interdependence of the water relaxation decay on blood flow, blood volume, oxygen extraction, vascular architecture and other factors. This relaxation decay is only measured at a single point with conventional fMRI methods, which limits sensitivity and specificity. Furthermore, the widely used echo-planar-imaging (EPI) technique additionally suffers from image ghosting due to interference of signals acquired with opposite readout gradient polarity, which makes phase sensitive image reconstruction difficult. In our early work we have introduced PEPSI as a method to map the change in water spectra during functional brain activation (38), which however had limited temporal resolution. More recently we used multi-echo EPI (39), which enables quantitative mapping of T2*, but like all EPI based techniques suffers from ghosting artifacts and is thus not suitable for quantitative phase sensitive mapping. Single-shot phase sensitive MR spectroscopic mapping of the water relaxation decay has the potential to provide considerably improve quantification of functional MRI, since the time course and phase of the decaying signal carry information about the blood volume, the blood vessel diameter distribution and intra-vascular signals in larger blood vessels (40,41). Single-shot acquisition is also important to reduce the influence of physiological fluctuations and movement.

This method is also applicable to spatial mapping chemical reactions for applications in material science and biology. For example, the spatial evolution of a chemical chain reaction could be observed. Such reactions are typically very fast and single-shot spectroscopic imaging acquisition schemes are thus important to avoid blurring of the spectroscopic images.

### REFERENCES

1. Duyn J H, Moonen C T. Fast proton spectroscopic imaging of human brain using multiple spin-echoes. Magn Reson Med 1993; 30(4):409-414.
2. Mansfield P. Multi-planar image formation using NMR spin echos. J Physics 1977; C10:L55-L58.
3. Adalsteinsson E, Irarrazabal P, Topp S, Meyer C, Macovski A, Spielman D M. Volumetric spectroscopic imaging with spiral-based k-space trajectories. Magn Reson Med 1998; 39(6):889-898.
4. Norris D G, Dreher W. Fast proton spectroscopic imaging using the sliced k-space method. Magn Reson. Med. 1993; 30:641645
5. Guimaraes A R, Baker J R, Jenkins B G, Lee P L, Weisskoff R M, Rosen B R, Gonzalez R G. Echoplanar chemical shift imaging. Magn Reson Med. 1999 May; 41(5):877-82.
6. Ebel A, Soher B J, Maudsley A A. Assessment of 3D proton MR echo-planar spectroscopic imaging using automated spectral analysis. Magn Reson Med 2001; 46(6): 1072-1078
7. Schuster C, Dreher W, Geppert C, Leibfritz D. Fast 3D 1H spectroscopic imaging at 3 Tesla using spectroscopic missing-pulse SSFP with 3D spatial preselection. Magn Reson Med. 2007 January; 57(1):82-9
8. Posse S, Tedeschi G, Risinger R, Ogg R, Le Bihan D. High speed 1H spectroscopic imaging in human brain by echo planar spatial-spectral encoding. Magn Reson Med 1995; 33(1):34-40.
9. Posse, S., Tedeschi, Risinger, G., Ogg, R., Le Bihan, D., High Speed 1H spectroscopic imaging, Magnetic Resonance in Medicine, 33, 34-40, 1995
10. Otazo, R., Mueller, B., Ugurbil, K., Wald, L. L., Posse, S. Signal-to-Noise Ratio and Spectral Line Width Improvements between 1.5 and 7 Tesla in Proton-Echo-Planar-Spectroscopic-Imaging (PEPSI). Magn Reson Med. 2006; 56(6): 1200-1210
11. Posse S, Dager S R, Richards T L, Yuan C, Ogg R, Artru A A, Muller-Gartner H W, Hayes C. In vivo measurement of regional brain metabolic response to hyperventilation using magnetic resonance: proton echo planar spectroscopic imaging (PEPSI). Magn Reson Med 1997; 37(6):858-865.
12. Dager S R, Layton M E, Strauss W, Richards T L, Heide A, Friedman S D, Artru A A, Hayes C E, Posse S. Human brain metabolic response to caffeine and the effects of tolerance. Am J Psychiatry 1999; 156(2):229-237.
13. Dager S R, Friedman S D, Heide A, Layton M E, Richards T, Artru A, Strauss W, Hayes C, Posse S. Two-dimensional proton echo-planar spectroscopic imaging of brain metabolic changes during lactate-induced panic. Arch Gen Psychiatry 1999; 56(1):70-77.
14. Posse, S., Otazo, R., Caprihan, A., Bustillo, J., Chen, H., Henry, P.-G., Marjanska, M., Gasparovic, C., Zuo, C., Magnotta, V., Mueller, B., Mullins, P., Renshaw, P., Ugurbil, K., Lim, K. O., Alger, J. R., Proton Echo Planar Spectroscopic Imaging of J-Coupled Resonances in Human Brain at 3 and 4 Tesla, Magn. Reson. Med. (2007), Vol 58, (2), 236-244
15. Mayer D, Levin Y S, Hurd R E, Glover G H, Spielman D M. Fast metabolic imaging of systems with sparse spectra: application for hyperpolarized 13C imaging. Magn Reson Med. 2006 October; 56(4):932-7.
16. Levin Y S, Mayer D, Yen Y F, Hurd R E, Spielman D M. Optimization of fast spiral chemical shift imaging using least squares reconstruction: application for hyperpolarized (13)C metabolic imaging. Magn Reson Med. 2007 August; 58(2):245-52.
17. Dydak U, Weiger M, Pruessmann K P, Meier D, Boesiger P. Sensitivity-encoded spectroscopic imaging. Magn Reson Med 2001; 46(4):713-722.
18. Dydak U, Pruessmann K P, Weiger M, Tsao J, Meier D, Boesiger P. Parallel spectroscopic imaging with spin-echo trains. Magn Reson Med 2003; 50(1): 196-200.
19. Pruessmann K P, Weiger M, Scheidegger M B, Boesiger P. SENSE: sensitivity encoding for fast MRI. Magn Reson Med 1999; 42:952-962.
20. Otazo R, Tsai S Y, Lin F H, Posse S, Accelerated Short-TE 3D Proton Echo-Planar Spectroscopic Imaging Using 2D-SENSE with a 32-Channel Array Coil, Magn Reson Med 2007, 58(6): 1107-16
21. Lin, F.-H., Tsai, S.-Y., Otazo, R., Caprihan, A., Wald, L. L., Belliveau, J. W., Posse, S., Sensitivity-encoded (SENSE) Proton-Echo-Planar-Spectroscopic-Imaging (PEP SI) in Human Brain, Mag. Reson. Med. 2007; 57 (2), 249-257
22. Tsai, S-Y, Posse, S., Otazo, R., Lin Y-R, Chung, H-W, Lin F-H, Accelerated Proton-Echo-Planar-Spectroscopy-Imaging (PEPSI) using GRAPPA with Large-N phased-Array Coils, Magn. Reson. Med., in press
23. Griswold M A, Jakob P M, Heidemann R M, Nittka M, Jellus V, Wang J, Kiefer B, Haase A. Generalized autocalibrating partially parallel acquisitions (GRAPPA). Magn Reson Med 2002; 47(6): 1202-1210.
24. Otazo, R., Jordan, R., Lin, F.-H., Posse, S., Superresolution parallel MRI, 2007 IEEE conference on Biomedical Imaging, San Antonio Tex., Abstract 2903, 2007
25. Otazo, R., Lin, F.-H., Wiggins, G., Jordan, R., Posse, S., Superresolution Parallel Spectroscopic Imaging. Proc. International Society for Magnetic Resonance in Medicine (ISMRM) 2008
26. Ardenkjaer-Larsen J H, Fridlund B, Gram A, Hansson G, Hansson L, Lerche M H, Servin R, Thaning M, Golman K. Increase in signal-to-noise ratio of >10,000 times in liquid-state NMR. Proc Natl Acad Sci USA 2003; 100:10158-10163.
27. Golman K, in't Zandt R, Thaning M. Real-time metabolic imaging. Proc Natl Acad Sci USA 2006; 103:11270-11275.
28. Golman K, Zandt R I, Lerche M, Pehrson R, Ardenkjaer-Larsen J H. Metabolic imaging by hyperpolarized 13C magnetic resonance imaging for in vivo tumor diagnosis. Cancer Res 2006; 66:10855-10860.
29. Golman K, Petersson J S. Metabolic imaging and other applications of hyperpolarized 13C1. Acad Radiol 2006; 13:932-942.
30. Posse S, Cuenod C A, Le Bihan D, Human brain: proton diffusion MR spectroscopy. Radiology 1993; 188: 719-725
31. Pfeuffer J, Tkac I, Gruetter R, Extracellular-intracellular distribution of glucose and lactate in the rat brain assessed noninvasively by diffusion-weighted 1H nuclear magnetic resonance spectroscopy in vivo. J Cereb Blood Flow Metab 2000; 20:736-46
32. Valette J, Guillermier M, Besret L, Hantraye P, Bloch G, Lebon V. Isoflurane strongly affects the diffusion of intracellular metabolites, as shown by 1H nuclear magnetic resonance spectroscopy of the monkey brain. J Cereb Blood Flow Metab. 2007 March; 27(3):588-96. Epub 2006 Jun. 21.
33. Posse, S., Cuenod, C. A., Le Bihan, D., Motion artifact compensation in 1H spectroscopic imaging, Journal of Magnetic Resonance 1993; Series B 102, 222
34. Bito Y, Hirata S, Nabeshima T, Yamamoto E. Echo-planar diffusion spectroscopic imaging. Magn Reson Med. 1995 January; 33(1):69-73.
35. Diffusion and perfusion: Magnetic resonance imaging, ed. Le Bihan D., Raven Press, New York, N.Y., 1995.
36. Hu J, Vartanian S A, Xuan Y, Latif Z, Soulen R L. An improved 1H magnetic resonance spectroscopic imaging technique for the human breast: preliminary results. Magn Reson Imaging. 2005 May; 23(4):571-6.
37. Jacobs M A, Barker P B, Bottomley P A, Bhujwalla Z, Bluemke D A. Proton magnetic resonance spectroscopic imaging of human breast cancer: a preliminary study. J Magn Reson Imaging. 2004 January; 19(1):68-75.
38. Posse, S., Wiese, S., Behr, D., Grosse-Ruyken, M.-L., Shah, N. J., Richards, T., Dager, S. R., Müller-Gartner, H.-W. Detection of Brain Activity by Oxygenation Sensitive Proton Echo Planar Spectroscopic Imaging (PEPSI). Abstract book: International Society for Magnetic Resonance in Medicine; 376,
39. Posse, S., Wiese, S., Gembris, D., Mathiak, K., Kessler, C., Grosse-Ruyken, M.-L., Elghawagh, B., Richards, T., Dager, S. R., Kiselev, V. G., Enhancement of BOLD-Contrast Sensitivity by Single-Shot Multi-Echo Functional MR Imaging, Magnetic. Resonance. Med., 42 (1): 87-97, 1999.
40. Kiselev, V. G., Posse, S., Theory of Susceptibility induced NMR Signal Dephasing in a Cerebrovascular Network., Physical Review Letters, 81:5696-5699, 1998.
41. Kiselev, V., Posse, S., Analytical Model of Susceptibility induced MR Signal Dephasing: Effect of Diffusion in a Microvascular Network., Magnetic Resonance in Medicine, 41 (3): 499-509, 1999.

### SUMMARY OF THE PRESENT INVENTION

The present invention has a magnetic resonance spectroscopic imaging (MRSI) method that allows collecting a complete spectroscopic image with one spectral dimension and up to three spatial dimensions in a single signal excitation. The method employs echo-planar spatial-spectral encoding combined with phase encoding interleaved into the echo-planar readout train and partial parallel imaging to reconstruct spatially localized absorption mode spectra. This approach enables flexible tradeoff between gradient and RF encoding to maximize spectral width and spatial resolution. Partial parallel imaging (e.g. SENSE or GRAPPA) is employed with this methodology to accelerate the phase encoding dimension. A preferred implementation is with the superresolution parallel MRI method (SURE-SENSE) described above, which accelerates along both the readout and phase encoding dimensions and thus enables particularly large spectral width and spatial resolution. The symmetrical k-space trajectory of this methodology is designed to compensate phase errors due to convolution of spatial and spectral encoding.

This method has important clinical and neuroscience applications. Hyperpolarized MR spectroscopy (MRS) provides investigators a unique opportunity to non-invasively monitor critical dynamic metabolic processes in vivo under both normal and pathologic conditions. Important applications include tumor diagnosis and treatment monitoring, as well as assessment of cardiac function. The rapid decay of the hyperpolarized signal requires fast MR spectroscopic imaging.

Spectroscopic imaging in moving organs, like the heart, is sensitive to movement artifact that results in blurring of the image and considerably regional differences in magnetic field inhomogeneity. Fast MR spectroscopic imaging techniques can substantially reduce motion sensitivity; thereby enhance the robustness of spatial-spectral encoding.

Spectroscopic imaging in the brain is sensitive to localized signal fluctuations due to blood pulsation or other physiological movement mechanisms that results in blurring of the image. Fast MR spectroscopic imaging techniques can substantially reduce motion sensitivity; thereby enhance the robustness of spatial-spectral encoding.

Spatial mapping of the apparent diffusion coefficients (ADCs) of metabolites enables assessment of several biophysical parameters such as viscosity, cell swelling, restriction in subcellular structures, cytoplasmic streaming, etc. that are complementary to intra- and extra-cellular water mobility measured with diffusion sensitive MRI. Single-shot MRSI would significantly reduce motion sensitivity, which precludes the use of conventional MRSI techniques.

Current functional MRI techniques lack quantification. Single-shot phase sensitive MR spectroscopic mapping of the water relaxation decay has the potential to provide considerably improve quantification of functional MRI, since the time course and phase of the decaying signal carry information about the blood volume, the blood vessel diameter distribution and intra-vascular signals in larger blood vessels.

Fast MR spectroscopic imaging techniques also enable spatial mapping of chemical reactions for applications in material science and reduce blurring in the spectroscopic images.

A pulse sequence that employs echo-planar spatial-spectral encoding combined with phase encoding interleaved into the echo-planar readout train and partial parallel imaging has been developed and implemented on 1.5 Tesla and 3 Tesla MRI scanners. Data were measured on a phantom with metabolite solutions and in the human brain. The data were reconstructed into spectroscopic images to show proof-of-concept.

The specific methods and compositions described herein are representative of preferred embodiments and are exemplary and not intended as limitations on the scope of the invention. Other objects, aspects, and embodiments will occur to those skilled in the art upon consideration of this specification, and are encompassed within the spirit of the invention as defined by the scope of the claims. It will be readily apparent to one skilled in the art that varying substitutions and modifications may be made to the invention disclosed herein without departing from the scope and spirit of the invention. The invention illustratively described herein suitably may be practiced in the absence of any element or elements, or limitation or limitations, which is not specifically disclosed herein as essential. The methods and processes illustratively described herein suitably may be practiced in differing orders of steps, and that they are not necessarily restricted to the orders of steps indicated herein or in the claims. As used herein and in the appended claims, the singular forms “a,” “an,” and “the” include plural reference unless the context clearly dictates otherwise. Thus, for example, a reference to “a host cell” includes a plurality (for example, a culture or population) of such host cells, and so forth. Under no circumstances may the patent be interpreted to be limited to the specific examples or embodiments or methods specifically disclosed herein. Under no circumstances may the patent be interpreted to be limited by any statement made by any Examiner or any other official or employee of the Patent and Trademark Office unless such statement is specifically and without qualification or reservation expressly adopted in a responsive writing by Applicants.

The terms and expressions that have been employed are used as terms of description and not of limitation, and there is no intent in the use of such terms and expressions to exclude any equivalent of the features shown and described or portions thereof, but it is recognized that various modifications are possible within the scope of the invention as claimed. Thus, it will be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

The invention has been described broadly and generically herein. Each of the narrower species and subgeneric groupings falling within the generic disclosure also form part of the invention. This includes the generic description of the invention with a proviso or negative limitation removing any subject matter from the genus, regardless of whether or not the excised material is specifically recited herein. In addition, where features or aspects of the invention are described in terms of Markush groups, those skilled in the art will recognize that the invention is also thereby described in terms of any individual member or subgroup of members of the Markush group.

All patents and publications referenced or mentioned herein are indicative of the levels of skill of those skilled in the art to which the invention pertains, and each such referenced patent or publication is hereby incorporated by reference to the same extent as if it had been incorporated by reference in its entirety individually or set forth herein in its entirety. Applicants reserve the right to physically incorporate into this specification any and all materials and information from any such cited patents or publications.

### BRIEF DESCRIPTION OF THE DRAWINGS

FIG. 1 shows the k-space trajectory for single-shot spatial-spectral encoding. This example shows an implementation that encodes an imaging matrix with 16 pixels in the phase encoding direction using 4-fold acceleration with partial parallel imaging. The phase encoding k-space positions (nR□k) are indicated on the right side where R denotes the acceleration factor (n: 1, . . . , 4). This trajectory is repeated N-times to encode spectroscopic images with N spectral points. Data are collected during the horizontal segments of the trajectory. The solid line represents the forward trajectory with readout gradients labeled 1, 2′, 3 and 4′. The dashed line represents the reverse trajectory with readout gradients 4, 3′, 2 and 1′. The ′ denotes readout gradients with negative polarity.

FIG. 2 illustrates the pulse sequence with the gradient switching scheme for the k-space trajectory shown in FIG. 1. The phase encoding gradient blips are interleaved between the alternating readout gradients.

FIG. 3 illustrates the data reconstruction pipeline. Even and odd echo data sets are formed after even-odd echo separation, data reordering and time reversal of even echo data. The even and odd echo raw data are spatially reconstructed with SENSE reconstruction based on coils sensitivity profiles measured in a separate non-water-suppressed fully sampled reference scan. The two data sets are combined after Fourier transformation across the spectral time domain and after phase and frequency correction based on the non-water-suppressed reference scan, resulting in an array of spatially reconstructed absorption mode spectra.

FIG. 4 shows the steps involved in SENSE reconstruction of the raw data after even-odd echo separation, data sorting and time reversal of even echo data.

FIG. 5 shows an example of an implementation of phase encoding in a third spatial dimension using blipped z-gradients interleaved into the pulse sequence shown in FIG. 2.

FIG. 6 shows the generation of multiple spin echoes that are individually phase encoded in the third spatial dimension using a phase encoding gradient in the z-direction positioned at the beginning of each readout gradient train. This gradient is changeded in amplitude from spin echo to spin echo to encode different parts of k-space. Z-gradient phase encoding pulses are interleaved into each readout gradient train as shown in FIG. 5 to accelerate encoding. This use of multiple phase encoded spin echoes combined with interleaved phase encoding gradient blips in the Z-direction further reduces the number of phase encoding gradient pulses interleaved into the readout gradient train, thus increasing spectral width in the reconstructed data.

FIG. 7 shows (a) spectroscopic images of choline (Cho), creatine (Cr) and N-acetyl-aspartate (NAA) measured in a spherical phantom at 1.5 T with an 8-channel coil array (TR/TE: 2 s/11 ms, voxel size: 5.8 cc, no averages: 8) using conventional PEPSI encoding (top). The corresponding data acquired with single-shot encoding are shown at the bottom. The Cramer-Rao lower bound (CRLB) thresholds for the conventional and single-shot PEPSI data were 20% and 50%, respectively. (b) Water-suppressed spectra from the black box in (a) acquired with conventional PEPSI encoding showing the spectral range from 1 to 3.8 ppm. (c) Corresponding spectra acquired with single-shot encoding.

FIG. 8 shows (a) spectroscopic images of choline (Cho), creatine (Cr) and N-acetyl-aspartate (NAA) measured in a spherical phantom at 3 T with a 12-channel coil array (TR/TE: 2 s/11 ms, voxel size: 3 cc) using conventional PEPSI encoding with 1 average (top). The corresponding spectroscopic images acquired with single-shot encoding and 16 averages are shown at the bottom. (b) The g-factor map of the SENSE reconstruction. (c) Water-suppressed spectra from the black box in (b) acquired with conventional PEPSI encoding and 1 average. (c) Corresponding spectra acquired with single-shot encoding and 16 averages showing the spectral range from 1.8 to 4 ppm.

FIG. 9 shows a comparison of conventional and single-shot PEPSI in human brain at 3 T measured with a 12-channel coil array in a supra-ventricular slice location (TR/TE: 2 s/11 ms, 3 cc voxel). (a) High resolution MRI (b) The g-factor map of the SENSE reconstruction. (c) Spectroscopic images of inositol (Ins), choline (Cho), creatine (Cr) and N-acetyl-aspartate (NAA) measured with a conventional PEPSI encoding with 1 average (top) and the corresponding spectroscopic images acquired with single-shot encoding and 16 averages (bottom). (d) Localized spectrum obtained with conventional PEPSI encoding from the voxel indicated in (a) with superimposed LCModel fit displaying a spectral range from 1.8 to 4 ppm. (e) Localized spectrum obtained with single-shot encoding from the voxel indicated in (a) with superimposed LCModel fit displaying a spectral range from 1.8 to 4 ppm.

FIG. 10 shows a table displaying slice averaged metabolite concentration values [mmol] in human brain at 3 T (+/−SD), measured with conventional phase encoded PEPSI and with single-shot PEPSI.

### DETAILED DESCRIPTION OF THE INVENTION

Theory

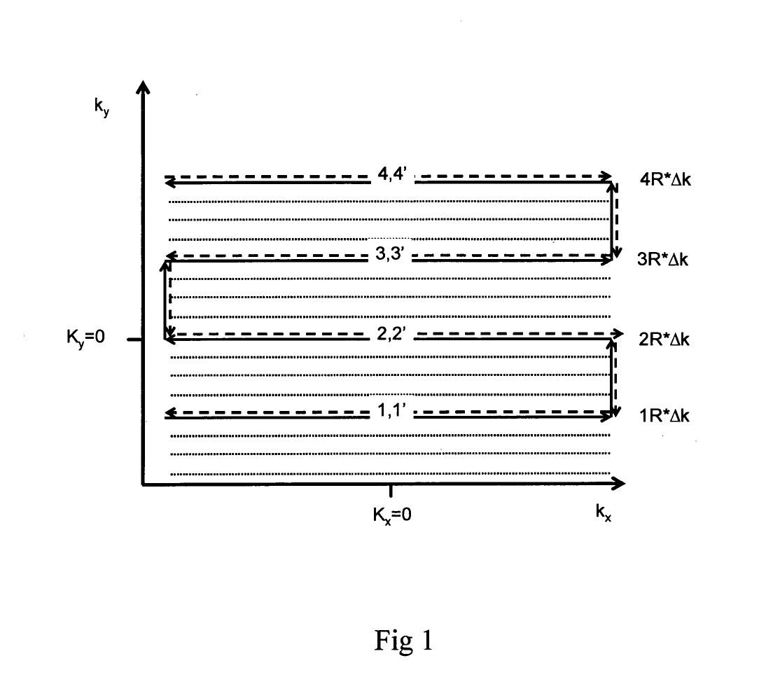

The single-shot MRSI method utilizes a train of alternating echo-planar readout gradients to simultaneously encode one spatial dimension and the spectral dimension. Spatial-spectral encoding in a second dimension is performed by interleaving a series of phase encoding gradient blips into the alternating readout gradient train between pairs of positive and negative readout gradient pulses to form a series of 2-dimensional spatial encoding modules with duration Δt (FIG. 1). Repetition of this spatial encoding module encodes spectral information with reconstructed spectral width 1/Δt. The number of repetitions determines the spectral resolution. The second spatial dimension is undersampled and a phased array radiofrequency receive coil that generates a sufficient number of spatially distinct sensitivity patterns is required to enable acceleration with parallel imaging. This combination of partial interleaved phase encoding and partial parallel imaging provides considerable acceleration of encoding speed as compared to previous methods.

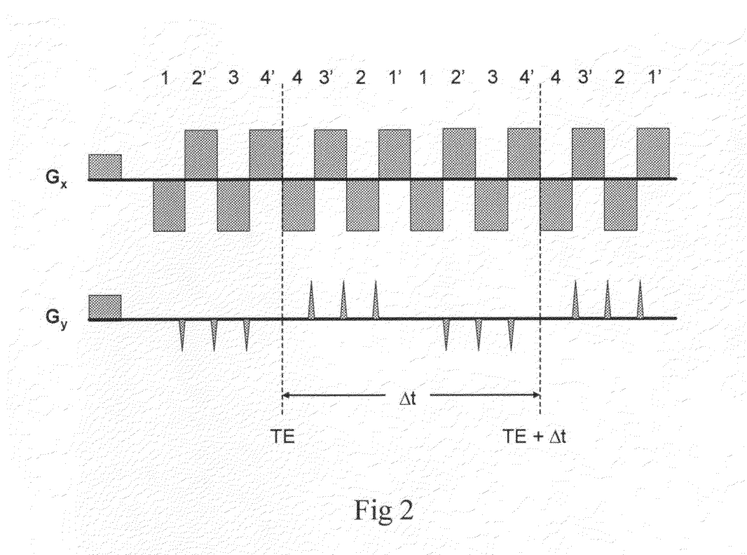

The k-space trajectory for each spatial encoding module is designed to (a) maximize signal-to noise ratio (SNR) by minimizing ADC dead time using ramp sampling, (b) minimize eddy current effects using uniform readout gradient inversion periodicity, and (c) obtain symmetrical chemical shift related phase evolution in the even and odd echo data. For each spatial encoding module a series of positive phase encoding gradients blips is followed by a series of negative phase encoding gradient blips, resulting in symmetrical forward and backward zig-zag trajectories in kx-ky-space (FIG. 2). Accelerated phase encoding steps through ky-space by skipping R ky-space lines. Solid and dashed lines in the trajectories correspond to positive and negative readout gradients. The end of the forward k-space trajectory of the first readout module is positioned at the spin echo time TE to minimize first order phase error upon combination of even and odd echo data. Data are then reconstructed using partial parallel imaging, for example using SENSE (19) or GRAPPA (23). Unlike with some other high-speed MRSI methods, this symmetric k-space trajectory enables reconstruction of pure absorption mode spectra. The benefits are narrow line width and the ability to acquire data at very short echo time, thereby maximizing measurement sensitivity.

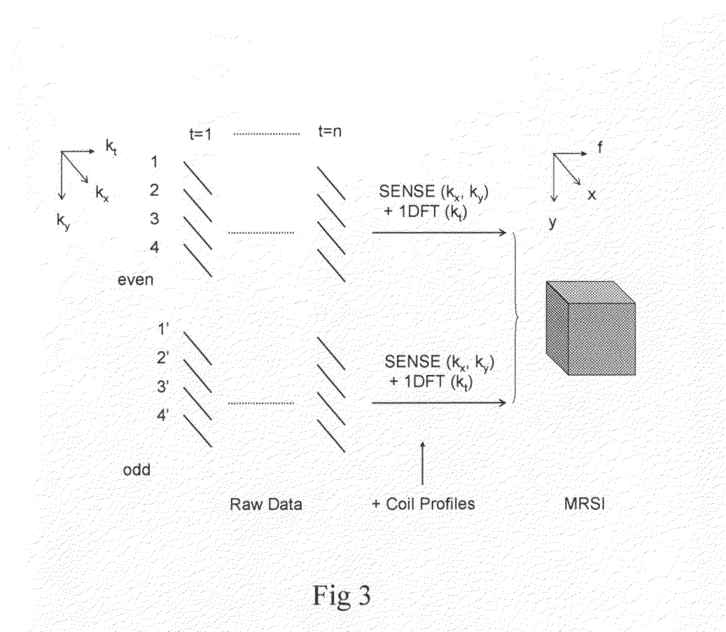

The solid and dashed lines in FIG. 1 are encoded using gradients. Data are collected during the horizontal segments. The solid line represents readout gradients 1, 2′, 3 and 4′, the dashed line represents readout gradients 4, 3′, 2 and 1′, which are shown in FIG. 3. Note that time points TE+n*Δt (where TE the echo time) are centered between readout gradients 4 and 4′ to achieve symmetric time delays around TE. First order phase modulation in the even and the odd echo data sets will cancel during combination of the data sets, resulting in pure absorption mode spectra. The benefit is feasibility of robust spectral fitting to achieve absolute quantification.

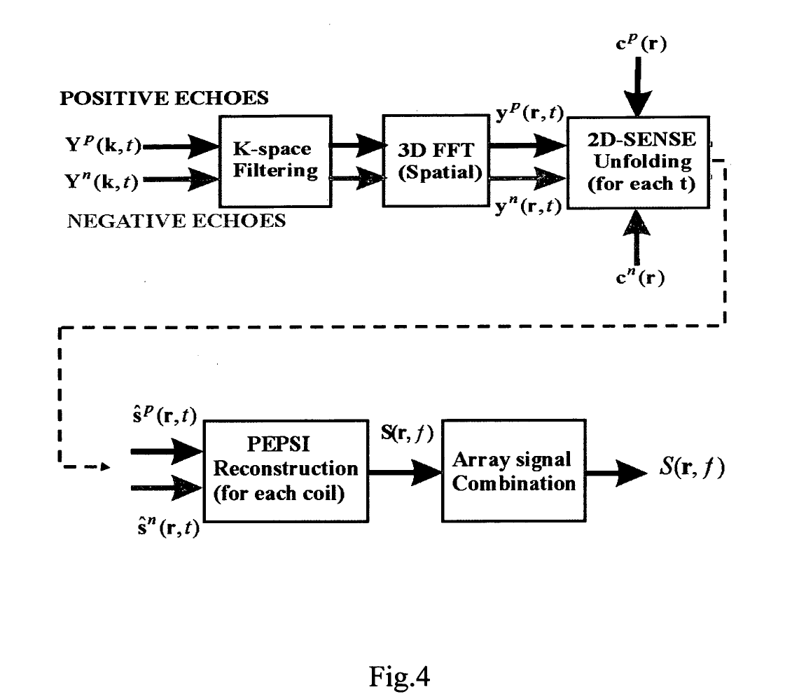

In this implementation the 4 data traces collected using readout gradients 1, 2, 3 and 4 are spatially reconstructed with SENSE reconstruction to form the odd echo data set as shown in FIGS. 3 and 4. Fourier Transformation across the repetitions of the module resolves spectral information. The 4 data traces collected using readout gradients 1′, 2′, 3′ and 4′ are spatially reconstructed with SENSE to form the even echo data set. Fourier Transformation across the repetitions of the module resolves spectral information.

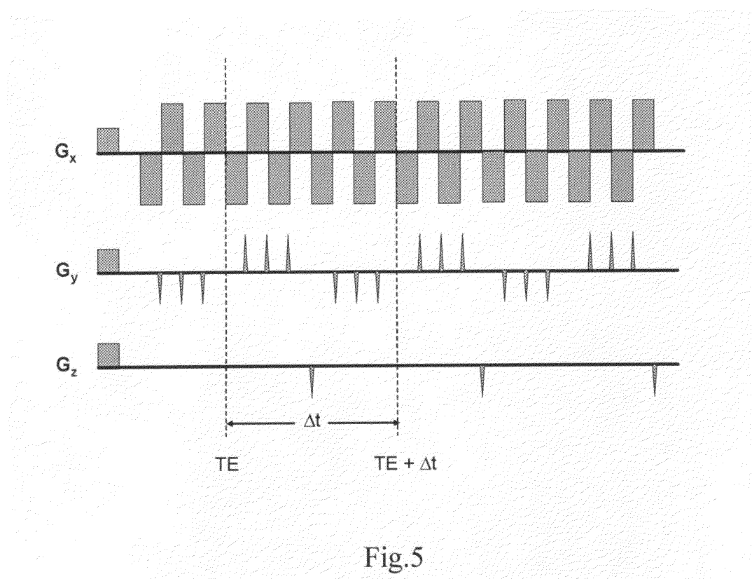

This encoding methodology can be extended to single-shot three-dimensional spatial encoding by interleaving a second set of phase encoding gradient pulses in the alternating readout gradient train to encode a third spatial dimension orthogonal to the directions of the readout gradients and the phase encoding gradients for the second spatial dimension. An example of such an implementation is shown in FIG. 5. Single-shot 3-dimensional spatial encoding in MRSI would dramatically reduce motion sensitivity as compared to previous methodology.

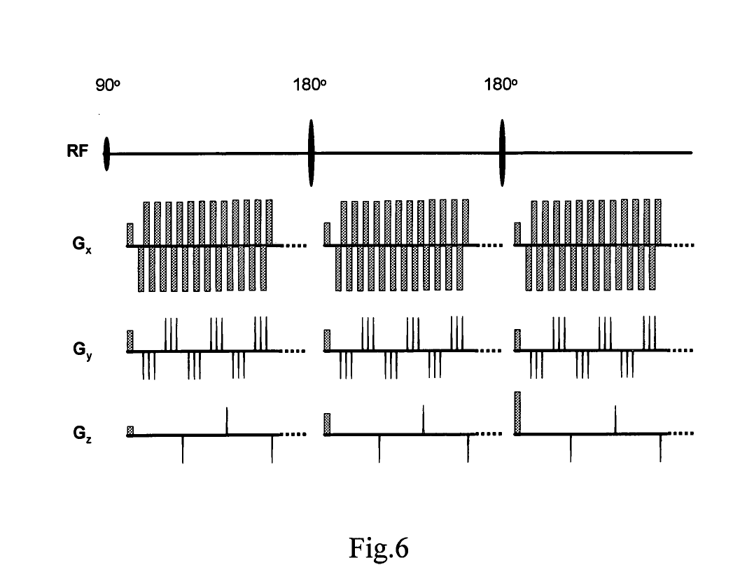

This single-shot encoding methodology can be further accelerated in one or two spatial dimensions by generating multiple spin echoes that are individually phase encoded. An example of such an implementation is shown in FIG. 6, which depicts the generation of multiple spin echoes that are individually phase encoded in the third spatial dimension using a phase encoding gradient in the z-direction at the beginning of each k-space trajectory that increments in amplitude from spin echo to spin echo, in addition to interleaving z-gradient phase encoding pulses into each readout gradient train as shown in FIG. 5. This further reduces the number of phase encoding gradient pulses interleaved into the readout gradient train, thus increasing spectral width in the reconstructed data. Narrow spectral width is a major limitation of previous single-shot MRSI methodology.

### Method Implementation

The pulse sequence was implemented on 1.5 T Siemens Sonata and 3 T Siemens Tim Trio scanners equipped with 8-channel and 12-channel head array coils, respectively. Spatial-spectral encoding was performed with 2048 trapezoidal readout gradients (240 μs duration), 100 μs phase encoding blips, 4-fold uniform acceleration of phase encoding to encode a 16×16 spatial matrix with 192 mm minimum FOV. Data were collected with 2-fold oversampling, regridded to correct the k-space trajectory distortion due to linear ramp sampling and decimated 2-fold to remove oversampling. The reconstructed spectral width was 390 Hz and the digital spectral resolution was 1.5 Hz. The pulse sequence included 3-pulse water suppression and 8-slice outer volume suppression.

Fully phase encoded data for coil sensitivity mapping and SNR comparison were obtained by adding a conventional phase encoding gradient along the y-axis and by extracting the 2 echoes that correspond to the center of the ky-space encoded by the blipped phase encoding gradients (labeled 2 and 2′ in FIG. 2). The extracted data thus have the same spectral width and spectral resolution as the single-shot encoded data, but sensitivity per unit time is reduced 2-fold as compared to single-shot encoding due to the 4-fold reduced data sampling density as a result of data extraction.

Data Acquisition, Reconstruction and Analysis

Measurements at short TE (11 ms) were performed on a spherical phantom filled with a metabolite solution with concentration values in the millimolar range and in healthy volunteers after obtaining institutionally approved consent. Coil sensitivity maps were estimated using spectral water images from an extra fully phase encoded non-water-suppressed (NWS) acquisition. Array geometry related noise amplification in the reconstruction was computed using the g-factor (19). Even and odd-echo data were reconstructed separately using SENSE reconstruction with regularization as described previously (20) (FIG. 3). Coil-by-coil SENSE reconstruction was generated by multiplying the combined SENSE reconstruction with the coil sensitivities in order to allow for application of spectral phase correction and frequency alignment to each channel separately. Exponential line broadening (2 Hz for 1.5 T and 4 Hz for 3 T) and Fourier transformation in the temporal domain were applied. The reconstructed NWS data were used to automatically correct zero-order phase error and frequency offset on a voxel-by-voxel basis. First order phase modulation in the even and the odd echo data sets canceled during combination of the two data sets, resulting in pure absorption mode spectra. Finally, the reconstructed multi-coil data were combined using sensitivity-weighted combination.

Spectra were quantified using LCModel fitting with analytically modeled basis sets. Errors in metabolite quantification in LCModel (% SD) are expressed in Cramer-Rao lower bound (CRLB, the lowest bound of the standard deviation of the estimated metabolite concentration expressed as percentage of this concentration), which when multiplied by 2.0 represent 95% confidence intervals of the estimated concentration values. SNR values were taken from LCModel output.

Metabolite concentration images at 3 T were created using the following thresholds to accept voxels: a) CRLB ≦30% for creatine (Cr) and N-acetyl-aspartate (NAA), CRLB ≦50% for choline (Cho), and inositol (Ins), and b) spectral line width (FWHM) ≦0.2 ppm. Larger CRLB thresholds (50% for Cho, Cr and NAA) were used for the single-shot data at 1.5 T due to lower SNR. Finally, the metabolite concentration maps were interpolated to a 128×128 matrix using zero-filling of the k-space data to improve visualization.

Results

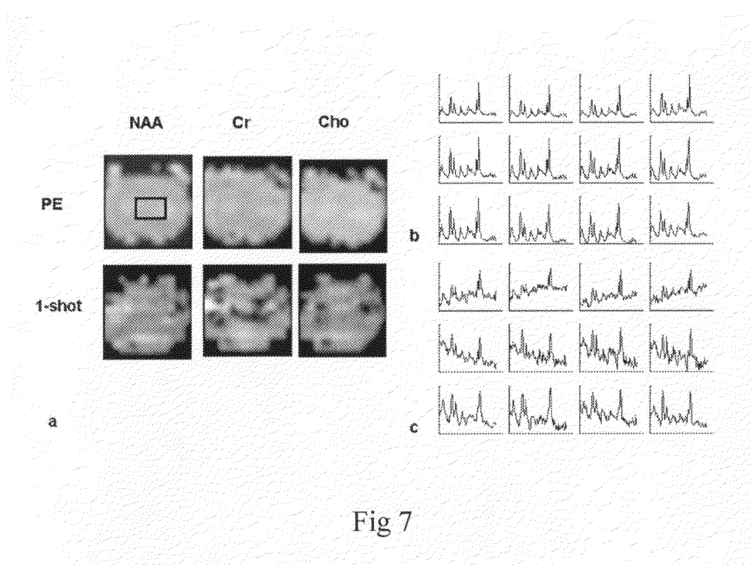

Data acquired at 1.5 T demonstrate feasibility of single-shot encoding with 6.2 ppm spectral width, which is adequate to encompass the major metabolites of interest in 1H brain spectroscopy. FIG. 7 shows metabolic images and water-suppressed spectra acquired on a phantom containing metabolite solutions at 1.5 T with conventional and single-shot PEPSI encoding (TR/TE: 2 s/11 ms, FOV: 192 mm, slice thickness: 40 mm, voxel size: 5.8 cc, no. averages: 8). The measurement time for conventional PEPSI encoding was 4 min 16 s. The corresponding data acquired with single shot MRSI using 4-fold SENSE acceleration and 8 averages with 16 s acquisition time show a similar spectral pattern with clearly identifiable singlet peaks. Even multiplet peaks (e.g. from glutamate at 2.35 ppm) are detectable. However, baseline distortion due to the rather large g-factor (mean: 4.7) of the receive coil array limits the spectral quality in the center of the phantom, resulting in increased fitting errors and inhomogeneity of the metabolic maps. The SNR of the single-shot data was approximately 2.7-fold lower than for the conventional data (2.5±1.4 vs. 6.8±2.7), consistent with (a) the 16-fold shorter measurement time of the single-shot data resulting in 4-fold decrease in SNR, (b) the 2-fold reduction in sensitivity of the fully phase encoded scan due to the extraction of the 2 central gradient echoes and (c) g-factor related noise amplification in the single-shot data. This confirms that the sensitivity (SNR per unit time and unit volume) of both methods when corrected for sampling efficiency and g-factor related noise enhancement is comparable, as expected theoretically. The spectral line width of the single-shot data was only slightly larger than that in the conventionally encoded data (5.0±2.5 Hz vs. 4.1±2.9 Hz).

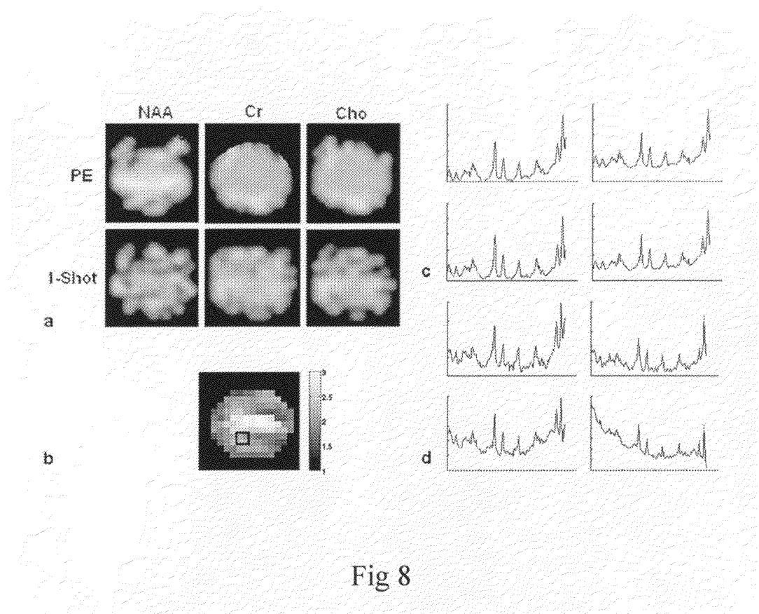

Data obtained at 3 T using a 12 channel array coil show improved performance of single-shot encoding as compared to 1.5 T due to the smaller g-factor (2.1±0.4) and higher SNR. FIG. 8 shows metabolic images and water-suppressed spectra acquired on a phantom at 3 T with conventional and single-shot PEPSI encoding (TR/TE: 2 s/11 ms, FOV: 230 mm, slice thickness: 15 mm, voxel size: 3 cc). Data were acquired with single average for conventional encoding and with 16 averages for single-shot encoding, resulting in the same measurement time for both methods. The 390 Hz spectral width results in aliasing of the NAA peak to the left side of the residual water peak. The spectral patterns measured with the two techniques are similar, but baseline distortion due to the g-factor related noise enhancement in the single-shot encoded data results in increased fitting errors and inhomogeneity of the metabolic maps. The average SNR of the single-shot data (7.5±5.7) was only slightly smaller than that in the fully encoded data (8.0±2.7), consistent with the approximately 2-fold g-factor related noise enhancement of the single-shot data and the 2-fold reduction in sensitivity of the fully phase encoded scan due to the extraction of the 2 central k-space lines.

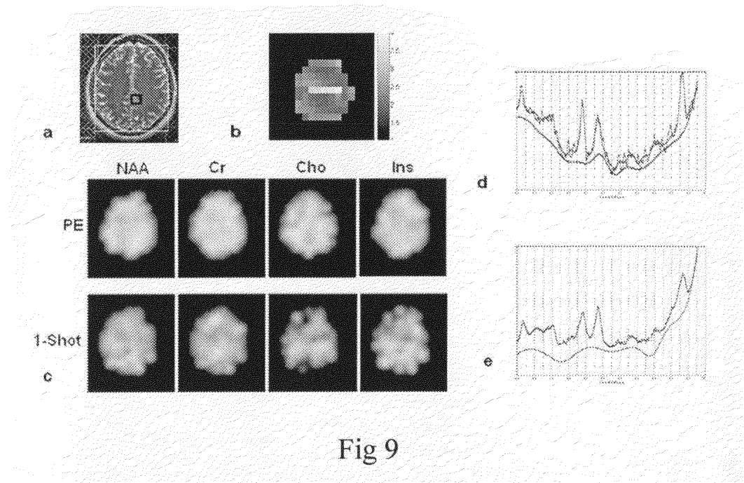

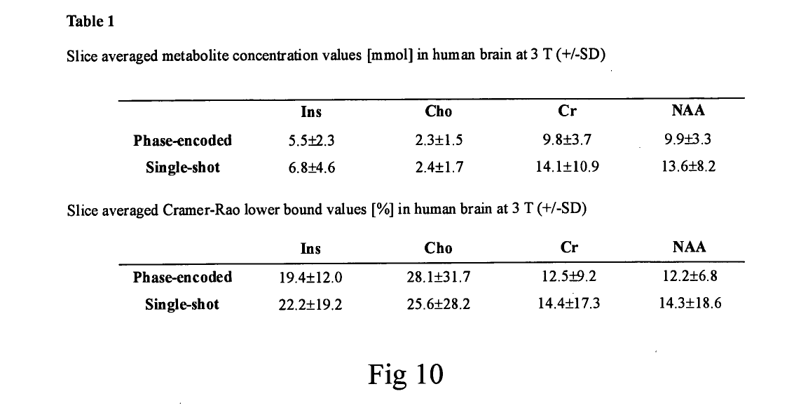

FIG. 9 shows in vivo data acquired at 3 T using a 12-channel array. Acquisition parameters were: TR/TE=2 s/11 ms, FOV: 230 mm, supra-ventricular axial slice, slice thickness: 15 mm, voxel size: 3 cc, no. averages for conventional encoding: 1, no. averages for single-shot encoding: 16). The location of the outer volume suppression slices along the periphery of the brain is shown in FIG. 6a. The mean g-factor (2.32±0.45) was comparable in magnitude to that in the phantom data. The g-factor map shows a central area of g-factor enhancement, as expected (FIG. 6b). The single-shot metabolite maps show relatively uniform spatial distributions of Ins, Cho, Cr and NAA, consistent with the maps obtained with conventional encoding, but larger spatial nonuniformity due to g-factor related noise enhancement (FIG. 9c). The spectral pattern with single-shot encoding (FIG. 9e) was similar to that obtained with conventional PEPSI encoding (FIG. 9d). Metabolite concentration values for the two methods (FIG. 10) were in the range reported in our previous study (14). The g-factor related noise enhancement in the single-shot data resulted in stronger baseline distortion and overestimation of the concentration values. The CRLBs of the two methods were similar in magnitude with larger variability in the single-shot data due to regional differences in g-factor related noise enhancement, as expected.

Compensation of Chemical Shift Displacement in the Readout Direction

Chemical shift evolution occurs during the application of the readout gradients, leading to chemical shift displacement of different chemical species in the readout direction. Parallel acquisition of the data during readout using phased array receive coil arrays with coils sensitivity variation along the readout direction provides complementary spatial information that is sampled instantaneously and thus not affected by chemical shift evolution. This additional spatial information can be used to deconvolve chemical shift evolution during collection of the readout signals to reduce chemical shift displacement in the readout direction.

What is claimed is:

1. An MRI apparatus that permits collecting a complete spectroscopic image with one spectral dimension and up to three spatial dimensions in a single signal excitation comprising:
an RF pulse transmitting device to excite nuclear spins in a circumscribed region;
a gradient pulse application device to encode k-space;
an NMR signal receiving device;
a spatial-spectral data collection, reconstruction and storage device; and
a pulse sequence control device to generate a high-speed magnetic resonance spectroscopic imaging (MRSI) pulse sequence using a train of alternating readout gradients to simultaneously encode one spatial and one spectral dimension.

2. An MRI apparatus according to claim 1, further comprising: acquiring MR signals with a radiofrequency phased array coil to spatially encode MR signals in up to three spatial direction using spatially inhomogeneous receive profiles, the spatial receive profiles enabling an R1-fold acceleration of phase encoding in on direction orthogonal to the readout gradient direction using partial parallel imaging, and the spatial receive profiles enabling an R2-fold acceleration of phase encoding in a second direction orthogonal to the readout and first phase encoding direction.

3. An MRI apparatus according to claim 1, further comprising: interleaving a multitude of phase encoding gradient pulses into the train of alternating readout gradient pulses to encode a second spatial dimension orthogonal to the direction of the readout gradients, the multitude being equal to M1/R1, where M1 is the required number of phase encoding steps for full k-space encoding in that dimension, R1 is the undersampling factor to accelerate encoding with partial parallel imaging.

4. An MRI apparatus according to claim 1, further comprising: interleaving a multitude of phase encoding gradient pulses into the train of alternating readout gradient pulses to encode a third spatial dimension orthogonal to the directions of the readout gradients and the first phase encoding gradients for the second spatial dimension, the multitude being equal to M2/R2, where M2 is the required number of phase encoding steps for full k-space encoding in that dimension and R2 is the undersampling factor in that dimension to accelerate encoding with partial parallel imaging.

5. An MRI apparatus according to claim 1, further comprising: repetitions of this interleaved set of phase encoding gradients in one or two spatial dimensions to encode spectral information, the number of repetitions being dependent on the desired spectral resolution.

6. An MRI apparatus according to claim 1, further comprising: encoding of a forward and a reverse k-space trajectory for each spatial encoding module using a series of positive and negative phase encoding gradient pulses.

7. An MRI apparatus that permits collecting a complete spectroscopic image with one spectral dimension and up to three spatial dimensions in a single signal excitation comprising:
an RF pulse transmitting device to excite nuclear spins in a circumscribed region;
a gradient pulse application device to encode k-space;
an NMR signal receiving device;
a spatial-spectral data collection, reconstruction and storage device; and
a pulse sequence control device to generate a high-speed magnetic resonance spectroscopic imaging (MRSI) pulse sequence using a train of alternating readout and interleaved phase encoding gradients to simultaneously encode up to three spatial and one spectral dimension.

8. An MRI apparatus according to claim 7, further comprising: generating multiple spin echoes that are individually phase encoded in one or two spatial dimensions to further accelerate spatial encoding.

9. An MRSI reconstruction method according to claim 7, further comprising: reordering of the acquired signals such that they represent consecutive phase encoding steps in k-space.

10. An MRSI reconstruction method according to claim 7, further comprising:
accelerate phase encoding using partial parallel image reconstruction methods, such as SENSE or GRAPPA, to reconstruct data that are undersampled in the phase encoding direction(s).

11. An MRSI reconstruction method according to claim 7, further comprising: reconstructing spatially localized absorption mode spectra.

12. An MRSI reconstruction method according to claim 7, further comprising: combining data acquired with positive and negative polarity readout gradient pulses to maintain signal-to-noise per unit time and unit volume and to cancel first order phase distortion in the reconstructed spectra.

13. An MRSI reconstruction method according to claim 7, further comprising: trading off between an interleaved gradient phase encoding, multiple spin echo encoding and an acceleration using partial parallel imaging in order to maximize a reconstructed spectral width.

14. A method for collecting a complete spectroscopic image with one spectral dimension and up to three spatial dimensions in a single signal excitation comprising the steps of:
transmitting an RF pulse to excite nuclear spins in a circumscribed region;
using a gradient pulse application to encode k-space;
receiving an NMR signal;
collecting spatial-spectral data, reconstruction and storage device; and
generating a high-speed magnetic resonance spectroscopic image (MRSI) pulse sequence using a train of alternating readout and interleaved phase encoding gradients to simultaneously encode up to three spatial and one spectral dimension to obtain the completed image.

15. A method according to claim 14, further comprising the step of: generating multiple spin echoes that are individually phase encoded in one or two spatial dimensions to further accelerate spatial encoding.

16. A method according to claim 14, further comprising the step of: reordering of the acquired signals such that they represent consecutive phase encoding steps in k-space.

17. A method according to claim 14, further comprising the step of: accelerating phase encoding using partial parallel image reconstruction methods, such as SENSE or GRAPPA, to reconstruct data that are undersampled in the phase encoding direction(s).

18. A method according to claim 14, further comprising the step of: reconstructing spatially localized absorption mode spectra and combining data acquired with positive and negative polarity readout gradient pulses to maintain signal-to-noise per unit time and unit volume and to cancel first order phase distortion in the reconstructed spectra.

19. A method according to claim 14, further comprising the step of: trading off between an interleaved gradient phase encoding, multiple spin echo encoding and an acceleration using partial parallel imaging in order to maximize a reconstructed spectral width.

20. A method according to claim 14, further comprising the step of: compensation of chemical shift dependent spatial displacement in the readout direction using deconvolution of chemical shift evolution based on parallel data acquisition with radiofrequency coil arrays that provide spatial encoding in the readout direction.
